(19) United States
(12) Patent Application Publication
(10) Pub. No.: US 2002/0006742 A1
(43) Pub. Date: Jan. 17, 2002

(54) TERMINAL BOX

(75) Inventors: TOSHITAKA HARA, KANAGAWA (JP); HISAO HONMA, TOKYO (JP); YUTAKA MATSUDA, KANAGAWA (JP); JUTARO MUKAI, SHIGA (JP); MITSUO TANAKA, SHIGA (JP)

Correspondence Address: FRISHAUF HOLTZ GOODMAN, LANGER & CHICK, 767 THIRD AVENUE, 25TH FLOOR, NEW YORK, NY, 100172023

(73) Assignee: THE FURUKAWA ELECTRIC CO., LTD., Tokyo (JP)

(21) Appl. No.: 09/424,797

(22) PCT Filed: Apr. 8, 1999
(86) PCT No.: PCT/JP99/01866

(30) Foreign Application Priority Data
Apr. 9, 1998 (JP) 10-97832
Apr. 16, 1998 (JP) 10-106420

(51) Int. Cl. H05K 1/00

(52) U.S. Cl. 439/76.2

(57) ABSTRACT

An electrical connection box 1 having circuit boards 41, 42 contained in a case. The circuit boards 41, 42 are assigned to a power supply system for start and travelling of an automobile and a power supply system for general loads, respectively.

### FIELD OF ART

The present invention relates to an electrical connection box installed in a vehicle, for example, in an engine room of an automobile and the like and used for connection of a wiring harness and the like.

### BACKGROUND ART

As the demand for amenity in driving increases, a vehicle, for example, an automobile tends to be equipped with a larger number of electrical devices and apparatuses such as an audio apparatus, a navigation apparatus, a television apparatus, an electrical antenna, an air conditioner, a rear window heater, a seat heater, a power seat, a suspension hardness control and the like.

To those on-vehicle electrical devices and apparatuses, power is supplied using wiring harnesses or the like via an electrical connection box placed near a battery in an engine room. The electrical connection box contains electrical components such as fuses for preventing excessive current flowing when a short circuit is produced between the wiring harnesses or the like and a body due to some trouble or when a load such as a motor breaks down, and relays operating in association with various control switches to control power supply to the on-vehicle electrical devices or apparatuses.

There is known an electrical connection box wherein, in view of heat emission, circuits of desired shapes are formed by bus bars and arranged between distribution boards, and fuses and relays are attached to the circuits, for example, from Japanese Unexamined Patent Publication (KOKAI) No. 59-28818.

Each bus bar is formed by stamping out a desired circuit shape from an electrical conductive plate of copper, copper alloy, brass or the like and then bending the stamped-out shape. The electrical circuits are formed by arranging the bus bars in a manner that they do not touch each other.

The electrical connection box using bus bars comprises many components. Therefore, it is difficult to downsize the electrical connection box. The production thereof needs many dies because in addition to stamping dies for bus bars, dies for molding synthetic resin into insulating spacers, which are arranged between bus bars and between a case and bus bars, are also needed. Therefore, cost of dies is large. Further, because of using many dies, it is difficult or practically impossible to modify the design of the electrical connection box.

In the engine room of an automobile in which the electrical connection box is to be installed, free space is very limited because many on-vehicle components are installed therein. In addition, the number of on-vehicle electrical devices and apparatuses tends to increase as stated above. Therefore, in order to save space, the design of the electrical connection box needs to take account of wiring between the electrical connection box and on-vehicle electrical devices and apparatuses.

Thus, there is a demand for an electrical connection box for an automobile which can be downsized keeping a heat emitting property equivalent to that of the electrical connection box using bus bars.

The present invention has been made in view of the above problems. The object thereof is to provide an electrical connection box which takes account of wiring to on-vehicle electrical devices and apparatuses, exhibits a heat emitting property equivalent to that of an electrical connection box using bus bars, and can be downsized.

### Disclosure of the Invention

In order to attain the above object, the present invention provides an electrical connection box having a circuit board contained in a case, wherein the circuit board is divided in accordance with power supply systems.

It is desirable that the electrical connection box is installed in an automobile and the circuit board is divided into one for a power supply system for start and travelling of the automobile and one for a power supply system for general loads.

It is desirable that the circuit board comprises a metal plate as a core.

### BRIEF DESCRIPTION OF THE DRAWINGS

FIG. 1 is an exploded perspective view of an electrical connection box of the present invention; FIG. 2 is a perspective view showing how circuit boards are contained in a case of the electrical connection box of FIG. 1; FIG. 3 is an enlarged cross-sectional view of a circuit board shown in FIG. 2; FIG. 4 is a circuit diagram showing an example of an electric system of an automobile in which the electrical connection box of FIG. 1 is installed; FIG. 5 is a perspective view of another modified example of circuit boards to be contained in the case of the electrical connection box of FIG. 1; FIG. 6 is an exploded perspective view of another embodiment of the electrical connection box of the present invention; and FIG. 7 is a cross-sectional view of a circuit board for use in the electrical connection box of FIG. 6.

### Best Mode of Carrying out the Invention

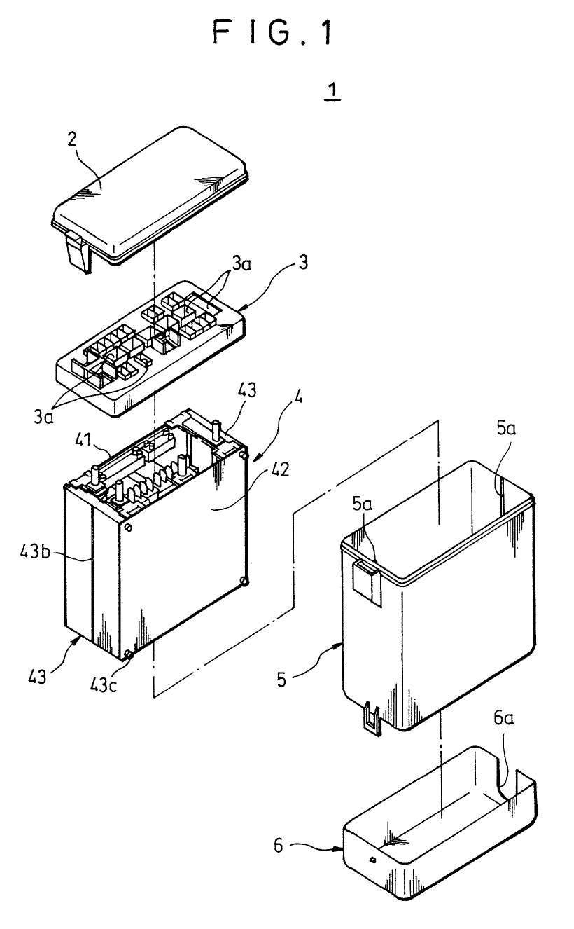

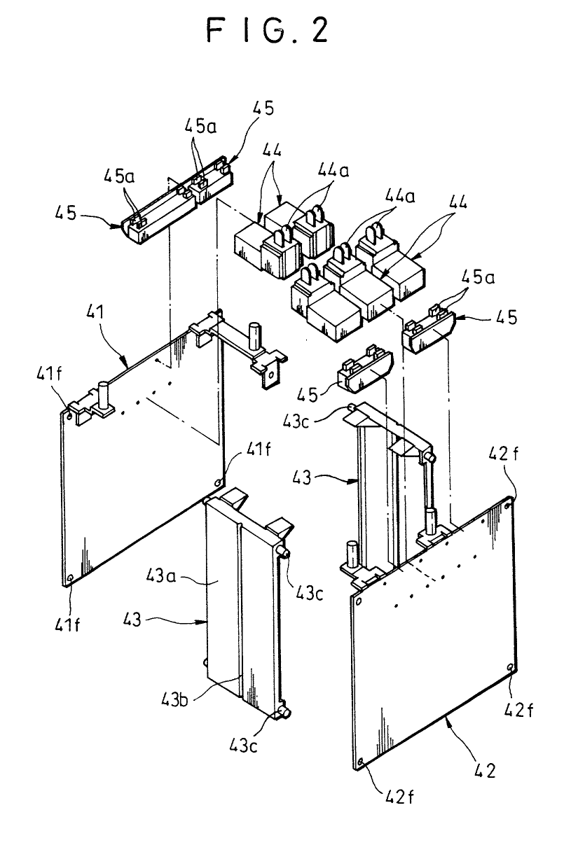

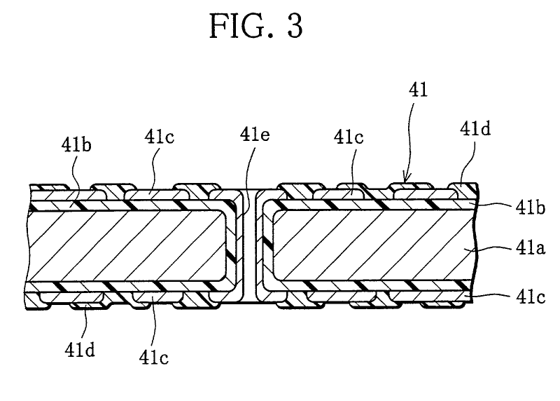

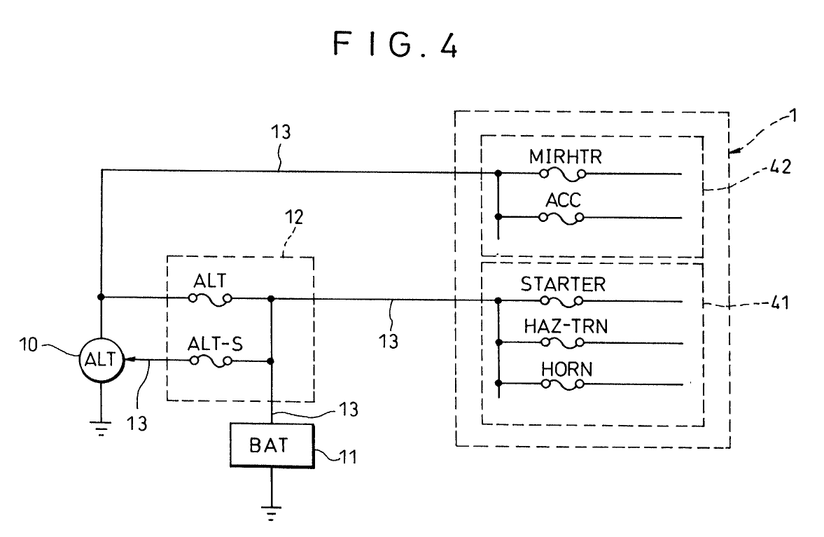

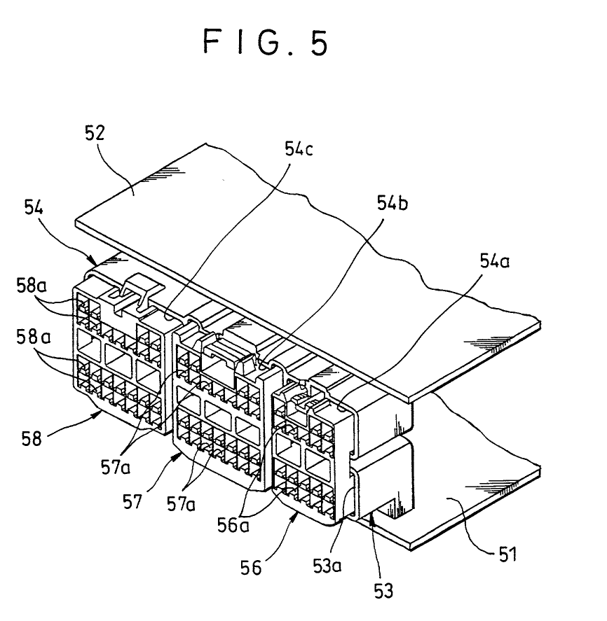

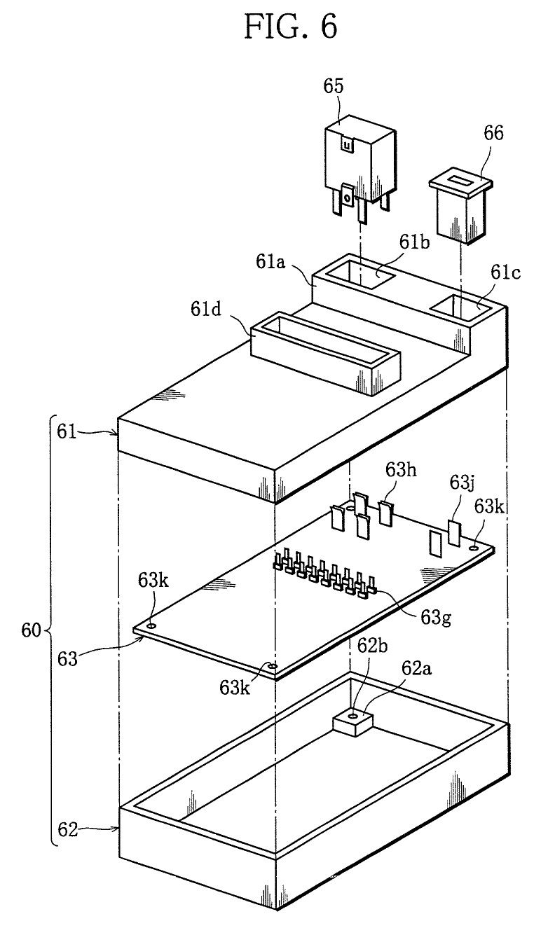

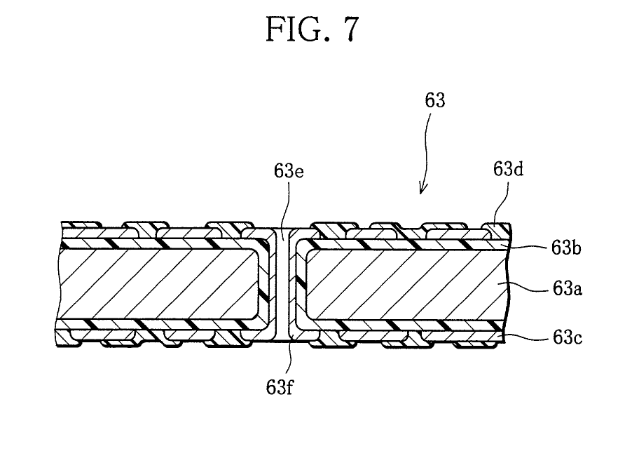

As an embodiment of the present invention, an electrical connection box to be installed in an engine room of an automobile will be described in detail referring to FIGS. 1 to 7.

As shown in FIG. 1, an electrical connection box 1 comprises an upper cover 2, a lid 3, a board unit 4, a case 5 and a lower cover 6. The upper cover 2, the lid 3, holding members 43 (described later) of the board unit 4, the case 5 and the lower cover 6 are molded from synthetic resin, particularly from synthetic resin having a good electrical insulating property (nylon, PBT(polybutylene terephthalate), PP(polypropylene) or the like).

The upper cover 2 is to prevent water from coming into the electrical connection box 1.

The lid 3 is put on the top of the case 5. The lid 3 is provided with openings 3a of various shapes in which terminals 44a, 45a of various fuse holders 44, 45 (described later) are set. Thus, the lid 3 doubles as a holder for fuses which are replaceable components.

As shown in FIG. 2, the board unit 4 comprises circuit boards 41, 42 having a good heat emitting property and two holding members 43, which are assembled into a unit.

A plurality of slow blow fuse holders 44, mini fuse holders 45, relays (not shown) and/or the like are attached to the circuit boards 41, 42, and the circuit boards 41, 42 are spaced apart and held by the holding members 43 on both sides. Each holding member 43 has a guide groove 43b on its outside surface 43a, and a plurality of pins 43c on both sides thereof. The guide groove 43b is provided to help insert the board unit 4 into the case 5. The pins 43c are provided to fit in location holes 41f, 42f (described later) of the circuit boards 41, 42.

The slow blow fuse holders 44 and mini fuse holders 45 are different in shape. They are provided to connect mini fuses (downsized blade fuses) (not shown) and slow blow fuses (not shown) electrically and mechanically to their related circuits formed on the circuit boards 41, 42. The mini fuses and slow blow fuses are provided to prevent excessive current flowing when a short circuit is produced between a wiring harness or the like and a body or when a load such as a motor breaks down. The slow blow fuse holders 44 and mini fuse holders 45 are provided with terminals 44a, 45a. The above mentioned relays are provided to operate in association with various control switches to control power supply to on-vehicle electrical devices and apparatuses.

Since the circuit boards 41, 42 have the same structure, only the structure of the circuit board 41 will be described. The description of the structure of the circuit board 42 will be omitted.

In order to have a good heat emitting property, the circuit board 41 has, for example, a structure shown in FIG. 3, wherein a metal plate 41a of aluminum, aluminum alloy, copper or copper alloy having a thickness of 0.2 to 1.2 mm is coated with an insulating layer 41b, and on the surface of the insulating layer, an electrical conductive layer 41c of copper foil and an electrical insulating resist layer 41d each having a thickness of 50 to 120 μm form conductive patterns of desired shapes. Through-holes 41e and location holes 41f (FIG. 2) are formed in the circuit board 41 at appropriate positions.

If the heat emitting property of the circuit board 41 is improved by forming the insulating layer 41b from adhesive insulating prepreg to which alumina powder or the like is added, the conductive patterns are allowed to have a smaller width for the same current capacity. This helps downsize the electrical connection box 1 further.

In the case of the circuit boards 41, 42, heat collected by the metal plate 41a is discharged from the electrical connection box 1 by being transferred via metal brackets (not shown) to an external portion and by being radiated from the case 5 and the metal brackets. If the metal brackets are fixed directly to a body of an automobile, heat. is transferred directly to the body, so that heat discharge is improved. If heat emitting members such as micro heat pipes are attached to the metal brackets, heat discharge is further improved.

The electrical connection box 1 of the present invention is characterized in that two circuit boards are each assigned to one power supply system, that is, the circuit board 41 is assigned to a power supply system for start, traveling and the like of an automobile, and the circuit board 42 is assigned to a power supply system for general loads.

An example of an electrical system of an automobile in which an electrical connection box 1 of the present invention is installed will be described based on FIG. 4. The electrical connection box 1 is connected to an alternator 10, an on-vehicle battery 11 and a fusible link box (hereinafter referred to simply as “link box”) 12 via wires 13 such as wiring harnesses or the like.

Here, power for start, traveling and the like of an automobile, for example, power for a starter motor, hazard lamps, turn signal lamps, a horn and the like is supplied from the on-vehicle battery 11 to a circuit board 41 of the electrical connection box 1, while power for general loads, for example, power for accessories such as heaters for removing a blur on mirrors by heating, an audio apparatus, a seat heater and the like is supplied from the alternator 10 and the on-vehicle battery 11 to a circuit board 42.

A case 5 is a member of a rectangular tube shape for containing a board unit 4, and protrusions 5a are formed on the inside thereof at positions corresponding to guide grooves 43b of holding members 43 so that the protrusion 5a may be inserted in the guide grooves 43b. The case 5 may be made of aluminum alloy or the like in view of heat emission.

A lower cover 6 is attached to cover the bottom of the case 5. It is provided with an opening 6a from which cables are to be drawn.

The electrical connection box 1 of the above described structure is assembled by inserting the board unit 4 in the case 5, attaching a lid 3 and the lower cover 6 to cover the top and the bottom of the case 5, respectively, and setting an upper cover 2 on the lid 3, as shown in FIG. 1.

The assembled electrical connection box 1 has the separate circuit boards 41, 42 assigned to the power supply system for start and traveling of the automobile and the power supply system for general loads, respectively. Therefore, on-vehicle apparatuses and devices can be divided between the two circuit boards 41, 42, and wiring between the electrical connection box 1 and the on-vehicle apparatuses and devices can be shorter and simpler. Further, because of the use of the circuit boards 41, 42, the electrical connection box 1 can be downsized to such an extent that the volume thereof is one-third to half as large as the volume of a conventional electrical connection box using bus bars, keeping a heat emitting property equivalent to that of the conventional electrical connection box.

It may be so arranged that a plurality of connectors are provided in accordance with destinations of wiring harnesses and attached to circuit boards divided in accordance with power supply systems so that wiring harnesses having the same destination may be connected in a lamp, as in the case of circuit boards 51, 52 shown in FIG. 5.

Specifically, a circuit board 51 is a board to which power for start, traveling and the like of an automobile, for example, power for a starter motor, hazard lamps, turn signal lamps, a horn and the like is supplied from an on-vehicle battery 11, and it has a structure similar to that of the circuit board 41. As shown in FIG. 5, a male connector 53 having three receiving openings 53a to 53c (reference signs 53b and 53c are not shown) is attached to the circuit board 51 at its edge portion on its upper side (as viewed in FIG. 5).

A circuit board 52 is a board to which power for general loads, for example, power for accessories such as heaters for removing a blur on mirrors by heating, an audio apparatus, a seat heater and the like is supplied from an alternator 10 and the on-vehicle battery 11, and it has a structure similar to that of the circuit board 42. As shown in FIG. 5, a male connector 54 having three receiving openings 54a to 54c is attached to the circuit board 52 at its edge portion on its lower side (as viewed in FIG. 5).

To the circuit boards 51, 52, first, second and third female connectors 56, 57, 58 are attached in a manner that they fit in their corresponding receiving openings 53a and 54a, 53b and 54b, 53c and 54c, respectively, to thereby bridge the male connectors 53, 54.

To the female connectors 56 to 58, connectors provided at the ends of wiring harnesses are connected in accordance with their destinations in terms of electrical systems. The female connectors 56 to 58 also connects the circuit boards 51, 52. The female connectors 56 to 58 have a plurality of receiving holes 56a to 58a in which female terminals (not shown) are to be fitted. Thus, the wiring harnesses (not shown) having various destinations extend from behind the female connectors 56 to 58.

With the arrangement that the connectors provided at the ends of the wiring harnesses are connected to the female connectors 56 to 58 in accordance with their destinations in terms of electrical systems, the circuit boards 51 and 52 are connected with each other, and the wiring harnesses having the same destination in terms of electrical systems are connected in a lamp. Therefore, the number of connectors are reduced, and connecting members for connecting the circuit boards 51, 52 are not needed any longer.

An electrical connection box may have a structure described below, wherein a circuit board described below is used instead of the circuit boards 41 and 42 or circuit boards 51 and 52.

As shown in FIG. 6, an electrical connection box 60 comprises an upper case 61, a lower case 62 and a circuit board 63.

The upper case 61 has an insertion housing 61a formed on one side thereof, and a connector housing 61d formed at the center thereof. In the insertion housing 61a, a relay insertion hole 61b and a fuse insertion hole 61c are formed. There lay insertion hole 61b has a rectangular cross-section corresponding to the cross-section of a relay 65, and the fuse insertion hole 61c has a rectangular cross-section corresponding to the cross-section of a fuse 66. The connector housing 61d has a frame-like shape to hold connectors of wiring harnesses or the like. The connector housing 61d is provided at a position corresponding to terminals 63g for male connectors (described later) provided on the circuit board 63.

The lower case 62 is arranged opposite to the upper case 61 with the circuit board 63 interposed therebetween. The lower-case 62 has ribs 62 at its four corners of the bottom for use in positioning the circuit board 63 in the vertical direction. Each rib 62a has a screw hole 62b formed on its upper side.

The circuit board 63 is a printed circuit board mainly made of glass epoxy resin which is generally used for an electronic unit. As shown in FIG. 7, the circuit board 63 comprises a metal plate 63a as a core, an insulating layer 63b which covers the surface of the metal plate 63a, an electrical conductive layer 63c formed on the insulating layer 63b, and a resist layer 63d formed on the electrical conductive layer 63c.

The material of the metal plate 63a needs to be able to impart rigidity to the circuit board 63, but it is not restricted to any special one. A plate of aluminum, aluminum alloy, copper, copper alloy, iron or the like may be used for the metal plate 63a. Since aluminum, aluminum alloy, copper, copper alloy and the like have a high thermal conductivity, the metal plate 63 made of any of those materials can transfer the heat caused by heating of electrical components such as a relay 65, to the outside. Thus, a rise in temperature occurring locally in the metal plate 63 can be restrained. Among the above materials, aluminum is the most favorable for the metal plate 63a, because use of aluminum helps make the circuit board 63 light and improves the heat emitting property thereof, and it is easy to form holes in a plate of aluminum. It is favorable that when the plate 63a is an aluminum plate, it is 0.2 to 2.0 mm in thickness. Specifically, in view of improving the heat emitting property, the aluminum plate having a thickness of 0.5 mm or more is favorable. In view of making it easier to form holes, the aluminum plate having a thickness of 1.0 mm or less is favorable.

The insulating layer 63b is made of prepreg of glass fabric impregnated with epoxy resin, and covers the surface of the metal plate 63a. If epoxy resin to which alumina power or the like is added is used for the insulating layer 63b, thermal conductivity thereof is improved. The electric conductive layer 63c is, for example, made of copper foil having a thickness of 18 to 210 μm, and forms predetermined circuit patterns on the insulating layer 63b. The resist layer 63d is a coat of epoxy or the like provided to prevent oxidation and soldering of the electrical conductive layer 63c.

As shown in FIG. 7, through-holes 63e are formed in the circuit board 63 at predetermined positions. Each through-hole 63e is coated with an electrolytic copper coat 63f, which connects the circuit patters formed by the electric conductive layer 63c on the face and back sides of the circuit board 63.

The circuit board 63 is produced, for example, as follows:

First, holes having a size a little larger than the size of to-be-formed through-holes 63e are formed in a metal plate 63a at positions predetermined for the through-holes 63e.

Next, a layer of prepreg of glass fabric impregnated with epoxy resin is formed on both sides of the metal plate 63a, and an electrical conductive layer 63c of copper foil is formed on the layer of prepreg. Then, the metal plate 63a with the layer of prepreg and the electrical conductive layer 63c is subjected to pressure pressing in a vacuum heating furnace and thereby formed into a flat board. In this step, part of the epoxy resin with which glass fabric is impregnated melts, and the holes formed in the metal plate 63a are filled with the melted epoxy resin.

Then, the through-holes 63e are formed at the above mentioned predetermined positions, and the inside of each through-hole 63e is coated with an electrolytic copper coat 63f.

Then, desired circuit patterns are formed by patter etching, and last, a resist layer 63d is formed. Since the insulating layer of synthetic resin (for example, epoxy resin) is formed between the coat 63f and the metal plate 63a inside the through-hole 63e, insulation is ensured.

As shown in FIG. 6, on the circuit board 63, terminals 63g for male connectors are arranged at an appropriate position, for example, at the center, and terminals 63h on which a relay 65 is to be mounted and male terminals 63j for a fuse on which a fuse 66 is to be mounted are arranged at an end portion. Further, through-holes 63k are formed in the circuit board 63 at its four corners corresponding to the screw holes 62b of the lower case 62.

In this embodiment, two or more circuit boards 63 may be laid with an insulating material therebetween. The circuit board 63 may also have a structure wherein thin glass epoxy boards are laid on both sides of a core metal plate 63a with an insulating layer interposed.

The electrical connection box 60 of the above described structure is assembled as follows:

First, the circuit board 63 is placed on the ribs 62a of the lower case 62, and fastened to the ribs 62 by screws. Then the upper case 61 is set on the lower case 62, and the upper and lower cases are joined.

Then, for example, a plug-in type ISO relay 65 is inserted in the relay insertion hole 61b and connected to the terminals 63h on the board, and, for example, a fuse 66 for medium current (MC) is inserted in the fuse insertion hole 61c and connected to the male terminals 63j for a fuse. Thus, the electrical connection box 60 is assembled.

By inserting connectors (not shown) of wiring harnesses in the connector housing 61d of the assembled electrical connection box 60, electrical connection between on-vehicle electrical devices and apparatuses and a battery is established.

Since the electrical connection box 60 uses a relatively rigid aluminum plate as a core of the circuit board 63 contained therein, deflection of the circuit board 63 which tends to occur when a relay, a fuse or a connector of a wiring harness is attached to or detached from the circuit board is restrained. Therefore, separation of soldering portions which tends to occur with the deflection of the circuit board 63 is restrained, and electrical connection defectives are reduced. Ribs other than the ribs at the four corners, which used to be provided at the bottom of the lower case 62 for preventing the deflection of the circuit board, are not needed any longer. This makes the production of the lower case 62 easier.

By using the electrical connection box of the present invention, larger free space can be obtained in an engine room. Therefore, for example, a circuit board (a glass epoxy board will do) comprising a signal circuit for a CPU or the like may be installed in the free space, depending on the destination or grade of an automobile.

Further, for example, if through-holes are formed in the circuit boards 41, 42 and the metal plates 41a, 42a are connected by a conductor, the metal plates can serve as conductors. Thus, for example, the circuit boards 41, 42 can be electrically connected, and earth current can be made flow through the circuit boards 41, 42 to a vehicle body side.

### Industrial applicability

According to the first aspect of the present invention, there is provided an electrical connection box which takes account of wiring to on-vehicle electrical devices and apparatuses, keeps a heat emitting property equivalent to that of an electrical connection box using bus bars, and can be downsized.

According to the second aspect of the present invention, the electrical connection box is installed in an automobile, and the circuit board is divided into one for a power supply system for start and traveling of the automobile, and one for a power supply system for general loads. With this structure, wiring to on vehicle electrical devices and apparatuses can be shorter and simpler.

According to the third aspect of the present invention, a metal plate is used as a core of a printed circuit board. Therefore, deflection of the printed circuit board which tends to occur when a relay, a fuse or a connector of a wiring harness is attached to or detached from the printed circuit board is restrained. Therefore, occurrence of troubles such as separation of soldering portions from the circuit board due to a load thereon and connection defectives caused by such separation is restrained. Thus, reliability of the electrical connection box is improved.

Further, in the electrical connection box according to the third aspect which can restrain the deflection of the printed circuit board, the number of ribs, which used to be provided at predetermined positions on the lower case in order to prevent the deflection of the printed circuit board, can be reduced. Thus, work needed for mounting the printed circuit board is reduced, the printed circuit board can be designed with wider freedom, dies for cases can be designed more easily, and production cost of the electrical connection box can be reduced.

1. An electrical connection box having a circuit board contained in a case, wherein said circuit board is divided in accordance with power supply systems.

2. An electrical connection box according to claim 1, wherein electrical connection box is installed in an automobile, and said circuit board is divided into one for a power supply system for start and travelling of said automobile and one for a power supply system for general loads.

3. An electrical connection box according to claim 1 or 2, wherein said circuit board comprises a metal plate as a core.
